(19) United States
(12) Patent Application Publication
(10) Pub. No.: US 2019/0104615 A1
(43) Pub. Date: Apr. 4, 2019

(54) PRINTED WIRING BOARD AND METHOD FOR MANUFACTURING THE SAME

(71) Applicant: IBIDEN CO., LTD., Ogaki (JP)

(72) Inventors: Toshiki Furutani, Ogaki (JP); Yukinobu Mikado, Ogaki (JP); Yoshiki Matsui, Ogaki (JP); Yusuke Tanaka, Ogaki (JP)

(73) Assignee: IBIDEN CO., LTD., Ogaki (JP)

(21) Appl. No.: 16/145,590

(22) Filed: Sep. 28, 2018

(30) Foreign Application Priority Data
Sep. 29, 2017 (JP) 2017-190159

(51) Int. Cl. H05K 1/18; H05K 1/11; H05K 3/28; H05K 3/42

(52) U.S. Cl. CPC H05K 1/186; H05K 1/115; H05K 3/284; H05K 2203/0723; H05K 3/429; H05K 3/428; H05K 3/424

(57) ABSTRACT

A printed wiring board includes a core substrate, a first resin insulating layer formed on a first surface of the core substrate, a second resin insulating layer formed on a second surface of the core substrate on the opposite side of the first surface, an electronic component accommodated in opening portion formed in the core substrate, and a filling resin filling space formed between the electronic component and an inner wall of the opening portion and including resin material that is different from resin material forming the first and second resin insulating layers. The core substrate has a first conductor pattern forming a first outermost layer of the core substrate and a second conductor pattern forming a second outermost layer of the core substrate on the opposite side of the first conductor pattern, and the filling resin is filling spaces formed in the second conductor pattern of the core substrate.

### CROSS-REFERENCE TO RELATED APPLICATIONS

The present application is based upon and claims the benefit of priority to

Japanese Patent Application No. 2017-190159, filed Sep. 29, 2017, the entire contents of which are incorporated herein by reference.

### BACKGROUND OF THE INVENTION

### Field of the Invention

The present invention relates to a printed wiring board with a built-in electronic component and relates to a method for manufacturing the printed wiring board.

### Description of Background Art

Japanese Patent Laid-Open Publication No. 2008-244029 describes a method for manufacturing a printed wiring board, in which an electronic component is accommodated in an opening part of a core substrate and a space between the electronic component and an inner wall of the opening part is filled with a resin that forms a resin insulating layer laminated on the core substrate. The entire contents of this publication are incorporated herein by reference.

### SUMMARY OF THE INVENTION

According to one aspect of the present invention, a printed wiring board includes a core substrate, a first resin insulating layer formed on a first surface of the core substrate, a second resin insulating layer formed on a second surface of the core substrate on the opposite side with respect to the first surface, an electronic component accommodated in an opening portion formed in the core substrate, and a filling resin filling a space formed between the electronic component and an inner wall of the opening portion and including resin material that is different from resin material forming the first and second resin insulating layers. The core substrate has a first conductor pattern forming a first outermost layer of the core substrate and a second conductor pattern forming a second outermost layer of the core substrate on the opposite side with respect to the first conductor pattern, and the filling resin is filling spaces formed in the second conductor pattern of the core substrate.

According to another aspect of the present invention, a method for manufacturing a printed wiring board includes preparing a core substrate having a first conductor pattern forming a first outermost layer of the core substrate and a second conductor pattern forming a second outermost layer of the core substrate on the opposite side with respect to the first conductor pattern, forming an opening portion in the core substrate, accommodating an electronic component in the opening portion formed in the core substrate, filling a filling resin into a space formed between the electronic component and an inner wall of the opening portion of the core substrate, and forming resin insulating layers on a first surface and a second surface of the core substrate, respectively. The filling of the filling resin includes forming a resin layer including the filling resin on the second conductor pattern of the core substrate such that the filling resin fills spaces formed in the second conductor pattern, and polishing the resin layer such that the second conductor pattern is exposed, and the forming of the resin insulating layers includes forming one of the resin insulating layers on the second surface of the core substrate after the resin layer is polished.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional side view of a printed wiring board according to a first embodiment;

FIGS. 2A and 2B are cross-sectional side views illustrating manufacturing processes of the printed wiring board;

FIGS. 3A and 3B are cross-sectional side views illustrating manufacturing processes of the printed wiring board;

FIGS. 4A and 4B are cross-sectional side views illustrating manufacturing processes of the printed wiring board;

FIGS. 5A and 5B are cross-sectional side views illustrating manufacturing processes of the printed wiring board;

FIG. 6 is a cross-sectional side view illustrating a manufacturing process of the printed wiring board:

FIG. 7 is a cross-sectional side view illustrating a manufacturing process of the printed wiring board;

FIG. 8 is a cross-sectional side view illustrating a manufacturing process of the printed wiring board; and

FIG. 9 is a cross-sectional side view of a printed wiring board according to another embodiment.

### DETAILED DESCRIPTION OF THE EMBODIMENTS

Embodiments will now be described with reference to the accompanying drawings, wherein like reference numerals designate corresponding or identical elements throughout the various drawings.

### First Embodiment

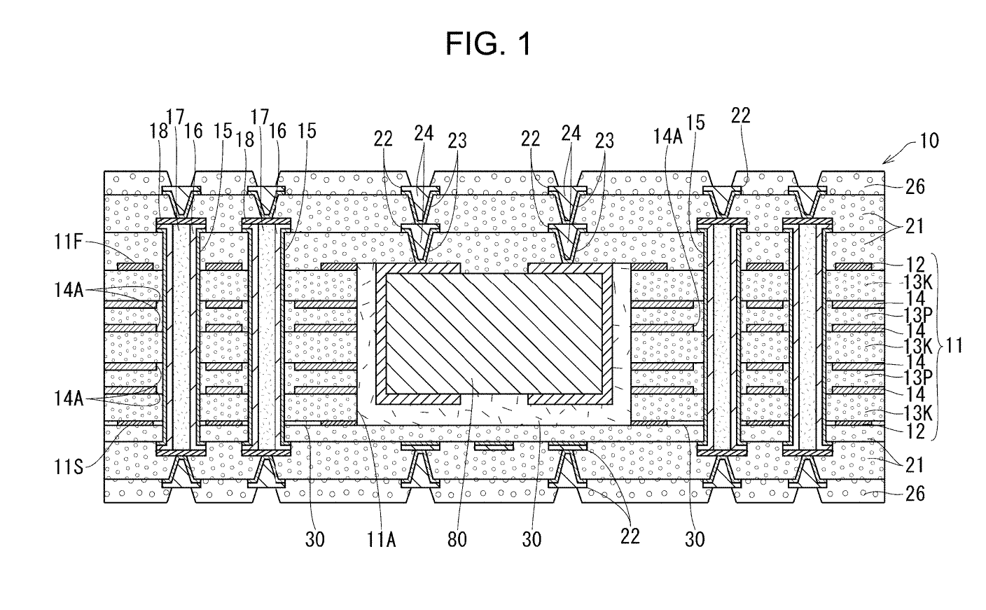

As illustrated in FIG. 1, a printed wiring board 10 according to the present embodiment includes a core substrate 11 having a first surface (11F) and a second surface (11S) on front and back sides thereof, resin insulating layers 21 formed on the first surface (11F) and on the second surface (11S) of the core substrate 11, and conductor patterns 22 formed on the resin insulating layers 21. Solder resist layers 26 are respectively formed on outermost conductor patterns 22.

The core substrate 11 is formed of a multilayer core and has a structure in which multiple insulating base materials (13K) having conductor patterns (12, 14) formed on front and back surfaces thereof are laminated with prepregs (13P) respectively sandwiched therebetween. A thickness of the conductor patterns 12 on the first surface (11F) side is larger than a thickness of the conductor patterns 12 on the second surface (11S) side. A thickness of the core substrate 11 is 150 μm or more and 2000 μm or less. Further, the thickness of the conductor patterns 12 on the first surface (11F) side is 15 μm, and the thickness of the conductor patterns 12 on the second surface (11S) side is 13 μm.

An opening part (11A) is formed in the core substrate 11. An electronic component 80 is accommodated in the opening part (11A). The electronic component 80 is, for example, a chip capacitor.

A space between the electronic component 80 and an inner wall of the opening part (11A) is filled with a filling resin 30. As a result. the electronic component 80 is fixed inside the opening part (11A). The filling resin 30 is formed of a resin different from a resin that forms the resin insulating layers 21.

The filling resin 30 is also filled in spaces between the conductor patterns 12 on the second surface (11S) side included in the core substrate 11. The resin that forms the resin insulating layers 21 is filled in spaces between conductor patterns 12 on the first surface (11F) side included in the core substrate 11.

Terminals of the electronic component 80 arranged on the first surface (11F) side are arranged flush with the conductor patterns 12 on the first surface (11F) side of the core substrate 11. The terminals of the electronic component 80 on the first surface (11F) side are connected to the conductor patterns 22 via via conductors 24. The via conductors 24 are formed by filling via holes 23 penetrating the resin insulating layers 21 with plating. Terminals of the electronic component 80 on the second surface (11S) side are connected to the conductor patterns 22 via the via conductors 24.

In the printed wiring board 10, through-hole conductors 16 connecting the conductor patterns 22 on the first surface (11F) side to the conductor patterns 22 on the second surface (11S) side are provided. The through-hole conductors 16 are formed on inner walls of through holes 15 penetrating the printed wiring board 10. An inner side of each of the through-hole conductors 16 is filled with a hole-filling resin 17. Both ends of each of the through-hole conductors 16 are covered by cover plating 18. Opening parts (14A) are provided in each of multiple conductor layers 14 included in the core substrate 11, and the through holes 15 are formed on inner sides of the opening parts (14A).

The printed wiring board 10 is manufactured as follows.

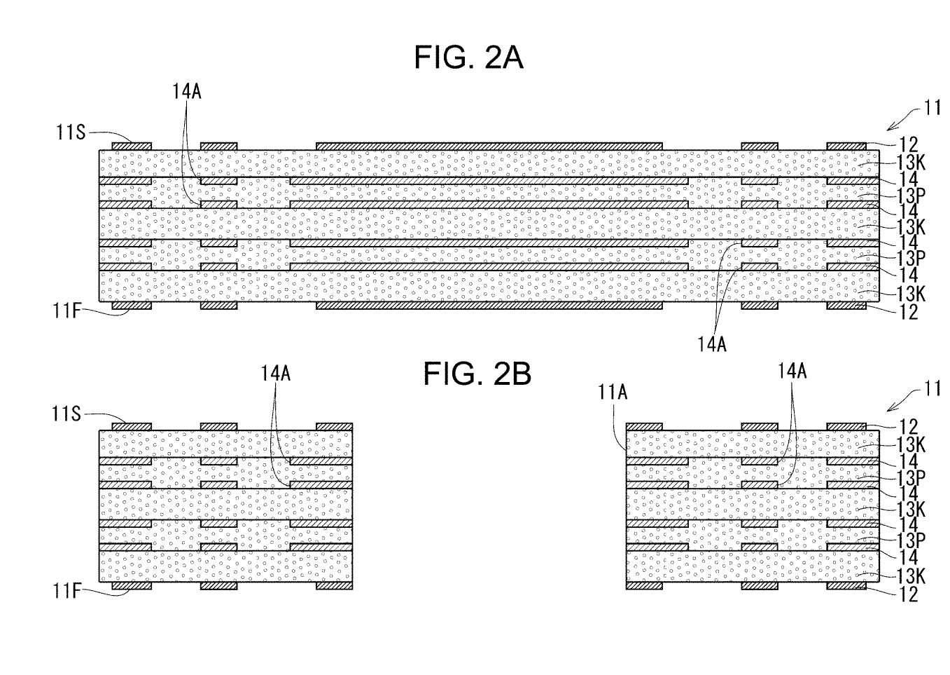

(1) As illustrated in FIG. 2A, the core substrate 11 is prepared. The opening part (11A) has not yet been formed in the core substrate 11. The resin layers 13 included in the core substrate 11 are each formed of, for example, a material obtained by impregnating a glass cloth with a resin such as a BT (bismaleimide triazine) resin, an epoxy resin or the like and curing the resin. The thickness of the conductor patterns 12 on the second surface (11S) side is substantially the same as the thickness of the conductor patterns 12 on the first surface (11F) side.

(2) As illustrated in FIG. 2B, the opening part (11A) is formed in the core substrate 11 by router processing.

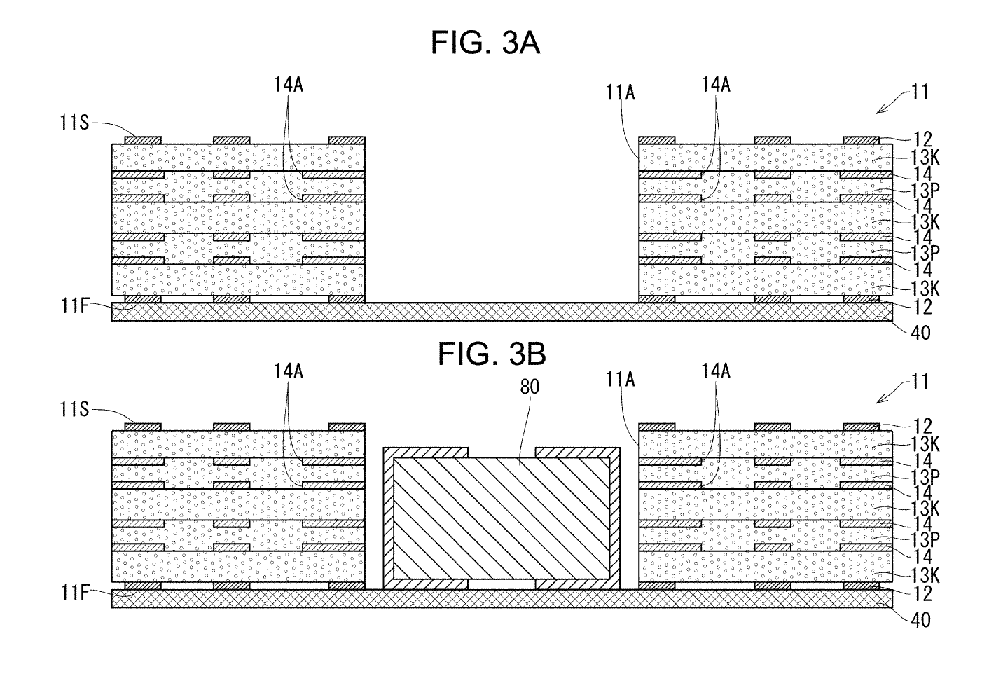

(3) As illustrated in FIG. 3A, the core substrate 11 is placed on an adhesive tape 40 and the opening part (11A) is closed. In this case, the first surface (11F) of the core substrate 11 opposes the adhesive tape 40.

(4) As illustrated in FIG. 3B, the electronic component 80 is accommodated in the opening part (11A).

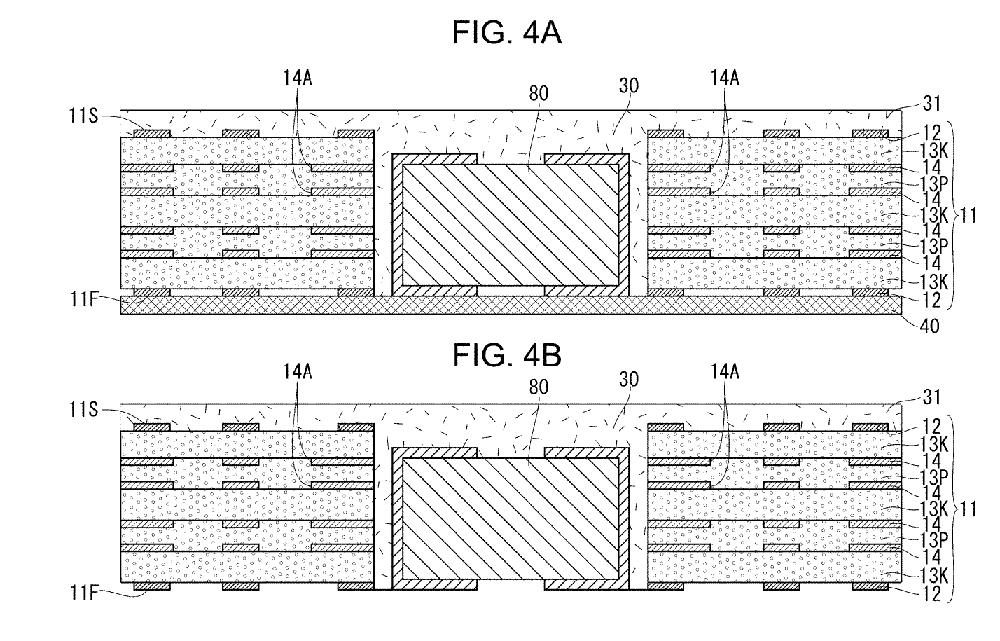

(5) As illustrated in FIG. 4A, the space between the electronic component 80 and the inner wall of the opening part (11A) is filled with the filling resin 30, and a resin layer 31 composed of the filling resin 30 is formed on the second surface (11S) of the core substrate 11. In this case, spaces between the conductor patterns 12 on the second surface (11S) side are filled with the filling resin 30. As a resin that forms the filling resin 30, a resin having an elastic modulus and a thermal expansion coefficient that are at least lower than those of the resin that forms the resin layers 13 of the core substrate 11 is effective. Specifically, a bismaleimide resin or the like having silica particles and polytetrafluoroethylene (PTFE) as a filler can be used.

(6) As illustrated in FIG. 4B, the adhesive tape 40 is peeled off.

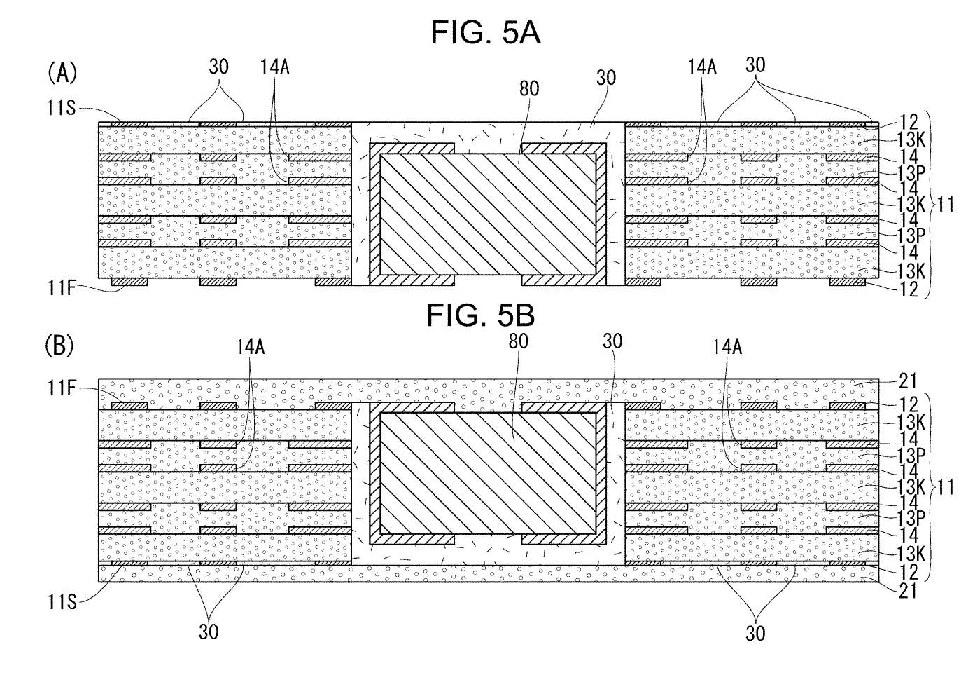

(7) As illustrated in FIG. 5A, a portion of each of the conductor patterns 12 on the second surface (11S) side and the resin layer 31 are polished, and the second surface (11S) of the core substrate 11 is flattened. In this case, the filling resin 30 filled in the spaces between the conductor patterns 12 on the second surface (11S) side remains without being polished. Further, the thickness of the conductor patterns 12 on the second surface (11S) side becomes smaller than the thickness of the conductor patterns 12 on the first surface (11F) side. The thickness of the conductor pattern 12 on the second surface (11S) side before polishing is 15 μm, and the thickness after polishing is 13 μm.

(8) As illustrated in FIG. 5B, the resin insulating layers 21 are respectively formed on the first surface (11F) and on the second surface (11S) of the core substrate 11. The resin insulating layers 21 are each fo led of, for example, a resin film that does not contain a core material but contains inorganic filler.

(9) The through holes 15 are formed by drilling, and the via holes 23 are formed by laser processing.

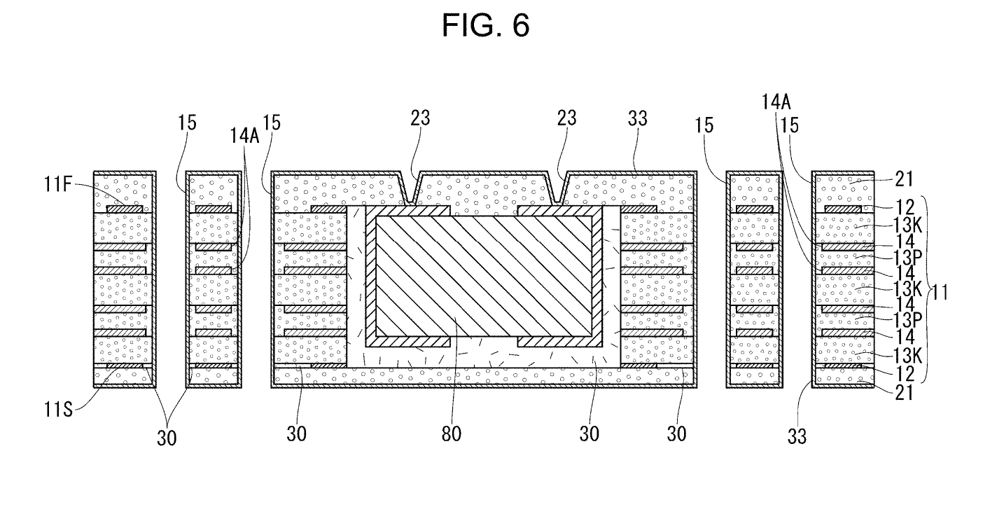

(10) An electroless plating treatment is performed. An electroless plating film 33 is formed on the resin insulating layers 21, in the via holes 23, and in the through holes 15 (FIG. 6).

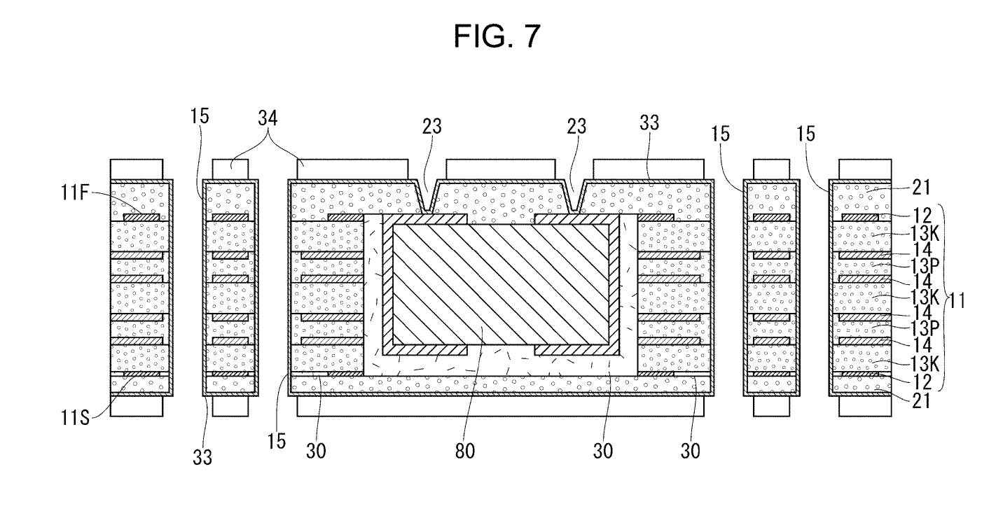

(11) As illustrated in FIG. 7, a plating resist 34 of a predetermined pattern is formed on the electroless plating film 33.

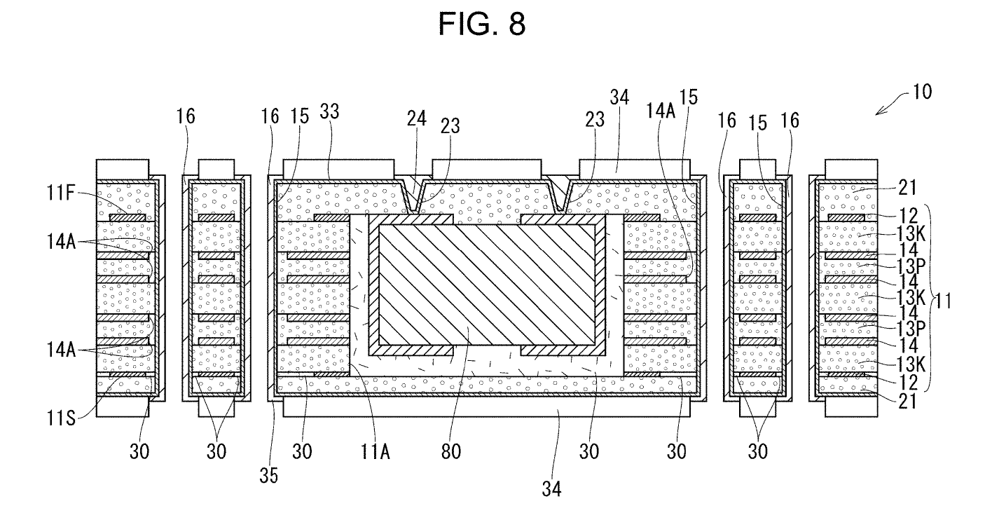

(12) An electrolytic plating treatment is performed. As illustrated in FIG. 8, the via conductors 24 are formed by filling the via holes 23 with electrolytic plating and the through-hole conductors 16 are formed by forming electrolytic plating on the inner walls of the through holes 15, and an electrolytic plating film 35 is formed on portions of the electroless plating film 33 exposed from the plating resist 34. Next, the inner sides of the through-hole conductors 16 are filled with the hole-filling resin 17, and the upper and lower ends of each of the through-hole conductors 16 are covered by the cover plating 18.

(13) The plating resist 34 is peeled off, and the electroless plating film 33 under the plating resist 34 is removed. Then, the conductor patterns 22 are formed by the remaining electroless plating film 33 and electrolytic plating film 35.

(14) Processes similar to the above-described processes (8) and (10)-(13) are performed and the resin insulating layers 21 and the conductor patterns 22 are formed on the front and back sides one stage at a time. Further, the solder resist layers 26 are respectively formed on the front and back sides. As a result, the printed wiring board 10 illustrated in FIG. 1 is completed.

The resin insulating layers 21 may each also be formed of a prepreg (a B-stage resin sheet obtained by impregnating a core material with a resin containing an inorganic filler). In this case, the conductor patterns 22 are formed by laminating a copper foil on each of the resin insulating layers 21 and then performing an electroless plating treatment and an electrolytic plating treatment.

In the method for manufacturing the printed wiring board 10 of the present embodiment, after the electronic component 80 is accommodated in the opening part (11A) of the core substrate 11, the space between the electronic component 80 and the inner wall of the opening part (11A) is filled with the filling resin 30, and the resin layer 31 composed of the filling resin 30 is formed on the conductor patterns 12 on the second surface (11S) side of the core substrate 11. Then, after a portion of each of the conductor patterns 12 and the resin layer 31 are polished, the resin insulating layer 21 is formed on the conductor patterns 12. As a result, the spaces between the conductor patterns 12 on the second surface (11S) side are filled with the filling resin 30.

In this way, in the present embodiment, since the resin insulating layer 21 is formed after the second surface (11S) of the core substrate 11 is flattened by polishing, the flatness of the resin insulating layer 21 is improved. In addition, since the resin layer 31 composed of the filling resin 30 is formed before polishing, the space between the electronic component 81 and the inner wall of the opening part (11A) can be reliably filled with the filling resin 30. As a result, the resin that forms the resin insulating layer 21 is prevented from entering the space between the electronic component 80 and the inner wall of the opening part (11A), and that the resin insulating layer 21 becomes thin near the electronic component 80 is prevented.

### Other Embodiments

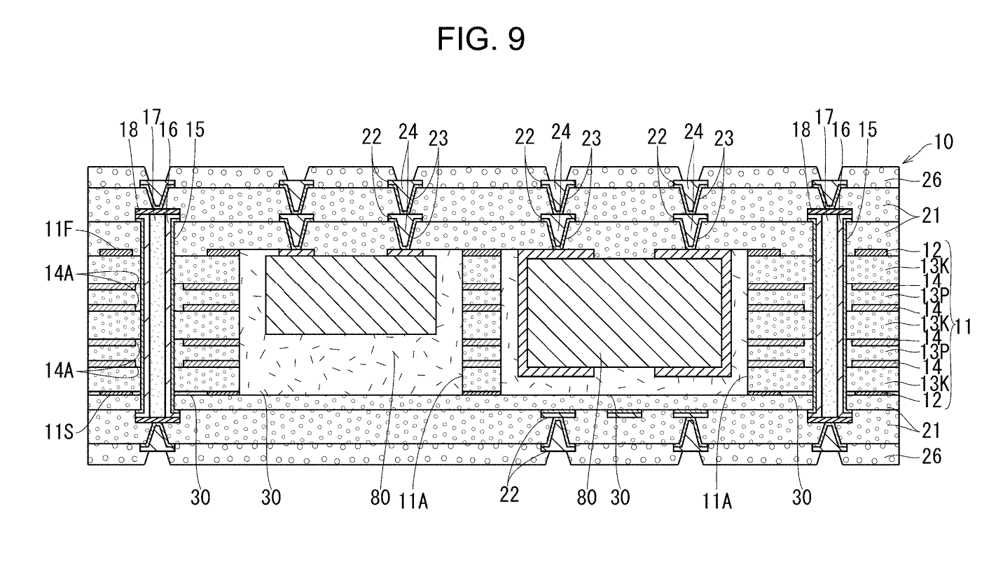

(1) The printed wiring board 10 may include multiple electronic components 80 having different thicknesses. In this case, it is possible that the multiple electronic components 80 are accommodated in one opening part (11A), or, as illustrated in FIG. 9, the electronic components 80 are respectively accommodated in multiple opening parts (11A) formed in the core substrate 11.

(2) In the above embodiment, the core substrate 11 may be a single-layer core having only one insulating base material (13K).

(3) The electronic component 80 may be a passive component such as a resistor or a coil, or may be an active component such as an IC chip formed of a semiconductor element.

(4) It is possible that the adhesive tape 40 is provided on both sides of a support plate, and printed wiring boards 10 are manufactured in parallel on both sides of the support plate.

(5) In the above embodiment, it is also possible that the core substrate 11 is placed in a manner that the electronic component 80 is accommodated in the opening part (11A) after the electronic component 80 is placed on the adhesive tape 40.

In the printed wiring board of Japanese Patent Laid-Open Publication No. 2008-244029, there may be a problem that flatness of the resin insulating layer near the electronic component is decreased.

A printed wiring board according to an embodiment of the present invention improves flatness of a resin insulating layer, and another embodiment of the present invention is to provide a method for manufacturing such a printed wiring board.

A printed wiring board according to an embodiment of the present invention includes: a core substrate having a first surface and a second surface respectively on front and back sides thereof and having conductor patterns on outermost layers; an opening part formed in the core substrate; an electronic component accommodated in the opening part; resin insulating layers that are respectively fomied on the first surface and on the second surface of the core substrate; and a filling resin that is formed of a resin different from a resin that forms the resin insulating layers and is filled in a space between the electronic component and an inner wall of the opening part. Spaces between the conductor patterns on the second surface side are filled with the filling resin.

A method for manufacturing a printed wiring board according to another embodiment of the present invention includes: preparing a core substrate having a first surface and a second surface respectively on front and back sides thereof and having conductor patterns on outermost layers; forming an opening part in the core substrate; accommodating an electronic component in the opening part; filling a space between the electronic component and an inner wall of the opening part with a filling resin; and forming resin insulating layers respectively on the first surface and on the second surface of the core substrate. Further, the filling of the space between the electronic component and the inner wall of the opening part with the filling resin includes: forming a resin layer composed of the filling resin on the conductor patterns on the second surface side and filling spaces between the conductor patterns on the second surface side with the filling resin; and exposing the conductor patterns on the second surface side by polishing the resin layer. Further, on the second surface, the resin insulating layer is formed after the resin layer is polished.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a core substrate;
a first resin insulating layer formed on a first surface of the core substrate;
a second resin insulating layer formed on a second surface of the core substrate on an opposite side with respect to the first surface;
an electronic component accommodated in an opening portion formed in the core substrate; and
a filling resin filling a space formed between the electronic component and an inner wall of the opening portion and comprising resin material that is different from resin material forming the first and second resin insulating layers,
wherein the core substrate has a first conductor pattern forming a first outermost layer of the core substrate and a second conductor pattern forming a second outermost layer of the core substrate on an opposite side with respect to the first conductor pattern, and the filling resin is filling spaces formed in the second conductor pattern of the core substrate.

2. The printed wiring board according to claim 1, wherein the first resin insulating layer is formed such that the resin material of the first resin insulating layer is filling spaces formed in the first conductor pattern of the core substrate.

3. The printed wiring board according to claim 1, wherein the electronic component is positioned in the opening portion of the core substrate such that a terminal structure of the electronic component is flush with the first conductor pattern of the core substrate.

4. The printed wiring board according to claim 1, wherein the core substrate has a thickness of 150 μm or more.

5. The printed wiring board according to claim 1, further comprising:
a second electronic component accommodated in a second opening portion formed in the core substrate,
wherein the second electronic component has a thickness that is different from a thickness of the electronic component.

6. The printed wiring board according to claim 1, wherein the core substrate is formed such that the first conductor pattern has a thickness that is larger than a thickness of the second conductor pattern.

7. The printed wiring board according to claim 1, further comprising:
a plurality of via conductors is formed through the first resin insulating layer such that the plurality of via conductors is connected to electrodes of the electronic component in the opening portion of the core substrate.

8. The printed wiring board according to claim 1, wherein the core substrate is a multilayer core comprising a plurality of prepregs and a plurality of insulating base materials such that each prepregs is sandwiched between two of the insulating base materials and that each of the insulating base materials has conductor patterns formed on both sides thereof.

9. The printed wiring board according to claim 2, wherein the electronic component is positioned in the opening portion of the core substrate such that a terminal structure of the electronic component is flush with the first conductor pattern of the core substrate.

10. The printed wiring board according to claim 2, wherein the core substrate has a thickness of 150 μm or more.

11. The printed wiring board according to claim 2, further comprising:
a second electronic component accommodated in a second opening portion formed in the core substrate,
wherein the second electronic component has a thickness that is different from a thickness of the electronic component.

12. The printed wiring board according to claim 2, wherein the core substrate is formed such that the first conductor pattern has a thickness that is larger than a thickness of the second conductor pattern.

13. The printed wiring board according to claim 2. further comprising:
a plurality of via conductors is formed through the first resin insulating layer such that the plurality of via conductors is connected to electrodes of the electronic component in the opening portion of the core substrate.

14. The printed wiring board according to claim 2. wherein the core substrate is a multilayer core comprising a plurality of prepregs and a plurality of insulating base materials such that each prepregs is sandwiched between two of the insulating base materials and that each of the insulating base materials has conductor patterns formed on both sides thereof.

15. The printed wiring board according to claim 3, wherein the core substrate has a thickness of 150 μm or more.

16. The printed wiring board according to claim 3, further comprising:
a second electronic component accommodated in a second opening portion formed in the core substrate,
wherein the second electronic component has a thickness that is different from a thickness of the electronic component, and that the second electronic component is positioned in the second opening portion of the core substrate such that a terminal structure of the second electronic component is flush with the first conductor pattern of the core substrate.

17. A method for manufacturing a printed wiring board, comprising:
preparing a core substrate having a first conductor pattern forming a first outei most layer of the core substrate and a second conductor pattern forming a second outermost layer of the core substrate on an opposite side with respect to the first conductor pattern;
forming an opening portion in the core substrate;
accommodating an electronic component in the opening portion formed in the core substrate;
filling a filling resin into a space formed between the electronic component and an inner wall of the opening portion of the core substrate; and
forming a plurality of resin insulating layers on a first surface and a second surface of the core substrate, respectively,
wherein the filling of the filling resin includes foifuing a resin layer comprising the filling resin on the second conductor pattern of the core substrate such that the filling resin fills spaces formed in the second conductor pattern, and polishing the resin layer such that the second conductor pattern is exposed, and the forming of the resin insulating layers includes forming one of the resin insulating layers on the second surface of the core substrate after the resin layer is polished.

18. The method for manufacturing a printed wiring board according to claim 17, wherein the forming of the resin insulating layers includes forming one of the resin insulating layers on the first surface of the core substrate such that resin material that forms the resin insulating layers fills spaces in the first conductor pattern.

19. The method for manufacturing a printed wiring board according to claim 17, wherein the accommodating of the electronic component includes fixing the core substrate and the electronic component on an adhesive tape such that when the core substrate is fixed on the adhesive tape, the first surface of the core substrate faces the adhesive tape, and that when the electronic component is fixed on the adhesive tape, terminals of the electronic component face the adhesive tape.

20. The method for manufacturing a printed wiring board according to claim 18, wherein the accommodating of the electronic component includes fixing the core substrate and the electronic component on an adhesive tape such that when the core substrate is fixed on the adhesive tape, the first surface of the core substrate faces the adhesive tape, and that when the electronic component is fixed on the adhesive tape, terminals of the electronic component face the adhesive tape.
